(19) United States
(12) Patent Application Publication
(10) Pub. No.: US 2007/0141753 A1
(43) Pub. Date: Jun. 21, 2007

(54) Group III nitride based compound semiconductor device and producing method for the same

(75) Inventors: Toshiya Uemura, Aichi-ken (JP); Shigemi Horiuchi, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD, Aichi-ken (JP)

(21) Appl. No.: 11/633,623

(22) Filed: Dec. 5, 2006

(30) Foreign Application Priority Data
Jun. 12, 2005 (JP) 2005-352727

(51) Int. Cl. H01L 21/00

(52) U.S. Cl. 438/113; 257/E21.238

(57) ABSTRACT

The present invention relates to method for producing a group III nitride based compound semiconductor device, including separating the device into individual chips by means of a dicing blade. A portion of an epitaxial layer where a dicing blade is to be positioned is partially or totally removed through etching, to thereby form a trench. An insulating film is formed on the bottom and on the side surfaces of the trench. A wafer is diced into chips in such a manner that the bottom of the trench is removed by means of the dicing blade without completely removing the side surfaces of the insulating film. The insulting film is formed on the side surfaces of the trench such that the film covers a p-type layer to an n-type layer included in group III nitride based compound semiconductor layers so as to prevent short circuit between the p-type layer and the n-type layer.

### BACKGROUND OF THE INVENTION

1. Field of the Invention

The present invention relates to a producing method for a group III nitride based compound semiconductor device. As used herein, the term “semiconductor optical device” collectively refers to a semiconductor device having any optical function of interest, including an energy conversion device for converting optical energy to electric energy or vice versa (e.g., a light-emitting device or a photoreceptor).

2. Background Art

It's been a long time since a group III nitride based compound semiconductor was found to be useful for producing a light-emitting device which emits green or blue light to UV light. Hitherto, such a light-emitting device has generally been produced through epitaxial growth of a group III nitride based compound semiconductor on an insulating hetero-substrate such as a sapphire substrate. Even when a conductive hetero-substrate is employed, considerable numbers of dislocations occurring during the growth remain in the formed epitaxial growth layer, which is problematic. In addition, while the epitaxial growth product is returned to ambient temperature, cracks attributed to difference in interlayer expansion coefficient are generated in a group III nitride based compound semiconductor layer, and the crack generation cannot be sufficiently prevented, which is also problematic.

Meanwhile, Japanese Patent No. 3418150, Japanese Kohyo Patent Publication Nos. 2001-501778 and 2005-522873, U.S. Pat. No. 6,071,795, and Kelly, et al., “Optical process for liftoff of group III-nitride films,” Physica Status Solidi (a) vol. 159(1997), p. R3-R4 disclose some techniques for producing semiconductor devices employing a substrate for epitaxial growth and a supporting substrate for use in a device, which are different from each other. Specifically, a group III nitride based compound semiconductor layer is epitaxially grown on a first substrate, and the produced group III nitride based compound semiconductor device is transferred to a second substrate.

### SUMMARY OF THE INVENTION

The present inventors have carried out extensive studies on employment of the above techniques for producing a group III nitride based compound semiconductor optical device. In the inventors' studies, a conductive substrate is employed as a supporting substrate, and an electrode bonded to a p-type layer being in contact with the supporting substrate is formed from a high-reflectance metal. In addition, on the opposite side, an electrode bonded to an n-type layer having a surface exposed through removal of a growth substrate is processed into a window frame form. Through employment of the inventors' technique, the light emitted from, for example, a group III nitride based compound semiconductor light-emitting device can be efficiently extracted through a window (i.e., area inside the window frame) where no frame-form electrode is provided on a surface of the n-type layer.

Meanwhile, during half-cutting of the device by means of a dicing blade, the side surfaces of the n-type layer and the p-type layer, sandwiching a side surface of the light-emitting area, are prone to be electrically shorted. The short circuit is caused by cutting chips of the multi-layer metal film for connection to the conductive substrate as well as by those of the group III nitride based compound semiconductor, and therefore, a considerably large current may be provided. Thus, an object of the present invention is to prevent short circuit between the side surfaces of the n-type layer and the p-type layer of the device.

According to a first aspect of the present invention, there is provided a method for producing a group III nitride based compound semiconductor device, including separating the device into individual chips by means of a dicing blade, the method comprising:

a portion of an epitaxial layer where a dicing blade is to be positioned is partially or totally removed through etching, to thereby form a trench;

forming insulating film on the bottom and on the side surfaces of the trench; and

performing dicing in such a manner that the bottom of the trench is removed by means of the dicing blade without completely removing the side surfaces of the insulating film,

wherein the insulting film is formed on the side surfaces of the trench such that the film covers a p-type layer to an n-type layer included in group III nitride based compound semiconductor layers so as to prevent short circuit between the p-type layer and the n-type layer.

Here the trench may reach a substrate or may not reach the substrate. It is adequate if only the side wall of the both of the p-type layer and the n-type layer are exposed in the trench. It is necessary not to completely remove the side surfaces of the insulating film.

According to a second aspect of the present invention, the etching and formation of the insulating film is carried out from one conduction-type layer of the group III nitride based compound semiconductor device, and the dicing by means of the dicing blade is carried out from the other conduction-type layer of the same device.

In the case where a group III nitride based compound semiconductor is epitaxially grown on a growth substrate, the grown stacked structure generally has a layer configuration for facilitating p-type activation in which a layer proximal to the growth substrate assumes an n-type layer and a layer distal to the substrate (i.e., upper layer) assumes a p-type layer. Therefore, the one conduction-type layer is p-type layer and the other conduction-type layer is n-type layer. However, if n-type upper layer can be produced through an improved technique, the one conduction-type layer may be n-type layer and the other conduction-type layer may be p-type layer.

According to a third aspect of the invention, before dicing through operation of the dicing blade, the method further comprises:

forming, on the first substrate, a group III nitride based compound semiconductor device;

forming an electrode on the uppermost layer of the device;

forming the trench;

forming the insulating film;

bonding a conductive second substrate, directly or by the mediation of a conductive film or a conductive multi-layer film, to the electrode-formed surface of the group III nitride based compound semiconductor device formed on the first substrate;

removing the first substrate from the bonded structure; and

forming an electrode on a newly exposed layer of the group III nitride based compound semiconductor device.

Here the conductive film or the conductive multi-layer film may be formed from at least one of a titanium (Ti), a nickel (Ni), a gold (Au) and a gold a gold-tin solder or a combination of these meal.

According to a fourth aspect of the present invention, there is provided a group III nitride based compound semiconductor device, which comprises:

a conductive substrate,

a first electrode joined to the conductive substrate directly or by the mediation of a conductive film or a conductive multi-layer film,

a group III nitride based compound semiconductor device layer in which at least a first conduction-type layer joined to the first electrode and a second conduction-type layer having a conduction type differing that of the first-conduction type layer are stacked,

a second electrode formed on the surface of the group III nitride based compound semiconductor device layer opposite the surface on which the first electrode has been formed, and

an insulating film extending along and proximal to the outer periphery of the device and formed so as to cover the side surfaces of the layers having an opposite conduction type and being included in the group III nitride compound semiconductor device layer.

Here for example the first conduction-type layer is a p-type layer and the second conduction-type layer is an n-type layer. And the first electrode is for the p-type layer and the second electrode is for the n-type layer.

According to the first aspect, before carrying out half-cutting by means of a dicing blade, the side surfaces of the n-type layer and the p-type layer of the device are covered with an insulating film. For example, at least a portion of the side surfaces of the p-type layer, the side surfaces of a functional layer such as a pn junction interface or a light-emitting layer, and at least a portion of the side surfaces of the n-type layer are covered. Through coverage with the insulating film, even when conductive dicing chips are deposited on a side surface of the device, pn short circuit can be prevented.

According to the second aspect, the present invention is particularly advantageous in the case where the etching direction for forming trenches and the dicing direction are different from each other; i.e., the uppermost layer during trench formation and that during dicing are different from each other.

According to the third aspect, the manufacturing method of the invention is particularly effective for a semiconductor stacked structure which is placed on an epitaxial growth substrate during etching and on a supporting substrate during dicing.

According to the fourth aspect, in the semiconductor device of the present invention, pn short circuit can be prevented, whereby yield of device chip production can be enhanced, and pn short circuit during use can be prevented.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIGS. 1A to 1J show cross-sections of a group III nitride based compound semiconductor light-emitting device 1000 showing production steps therefor;

### DETAILED DESCRIPTION OF PREFERRED EMBODIMENTS

The present invention is applicable to any type of group III nitride based compound semiconductor optical device, particularly to a light-emitting device having a light extraction region, and a photoreceptor having a light-accepting region. In the case of a semiconductor optical device having a supporting substrate, an electrode (e.g., a window-frame-shape electrode) is preferably formed, directly or by the mediation of a transparent electrode, on a group III nitride based compound semiconductor layer provided on a surface not being in contact with the supporting substrate. When positive and negative electrodes are provided so as to sandwich a light-emitting region, the supporting substrate is preferably a conductive substrate.

In the case where a semiconductor layer is separated from an epitaxial growth substrate by melting and decomposing a semiconductor layer (e.g., a GaN thin film) through laser beam radiation, a laser beam having a wavelength shorter than 365 nm is preferably employed. Alternatively, YAG laser beams (wavelength: 365 nm and 266 nm), an XeCl laser beam (wavelength: 308 nm), an ArF laser beam (155 nm), and a KrF laser beam (wavelength: 248 nm) are preferably employed. The laser beam radiation area for one operation; i.e., a unit radiation area, may be a rectangular area having a size of integral multiples of a chip size, in both the lateral and transverse directions. For example, when a chip (square) has a side of 500 μm, an unit radiation area of 2 mm×2 mm, which corresponds to an area including 4×4 chips, may be employed. Alternatively, a unit radiation area of 3 mm×3 mm, which corresponds to an area including 6×6 chips, may be employed. Such a unit laser beam radiation area is continuously scanned on a wafer without overlapping radiation areas. Such operation is preferred, since contours of the unit radiation area do not remain in a chip area. In other words, a semiconductor-melted area and a semiconductor-non-melted area do not co-exist in one single chip area during one single laser beam radiation operation, whereby production yield and characteristics of devices can be enhanced.

The stacked structure of a group III nitride based compound semiconductor is preferably formed through epitaxial growth. A buffer layer, which is formed on a growth substrate prior to epitaxial growth, may be formed not through epitaxial growth but through other techniques such as sputtering. No particular limitation is imposed on the specific procedure of the growth method such as epitaxial growth, and no particular limitation is imposed on the type of the epitaxial growth substrate, layer configuration, layer structure of functional layers (MQW, SQW, cladding layer, guide layer, etc.) including a light-emitting layer, handling of divided devices, etc. Detailed descriptions of the layer structure and manufacturing method of the semiconductor stacked structure may be omitted in the Embodiment described hereinbelow. However, in the present invention, any of the structures and the techniques known at the time of the present application may be employed in combination. Unless otherwise mentioned, these known layer structures and techniques are incorporated into the present invention.

The term “group III nitride based compound” refers in a narrower sense to an AlGaInN-based 4-component (including 2-component and 3-component) semiconductor itself and, in a broader sense, to such a semiconductor to which a donor impurity element or an acceptor impurity element for imparting conductivity thereto has been added. However, in general, the above semiconductor compounds may further contain another group III element or group V element as an additional or substituted element, or may contain any additional element for imparting other functions thereto. These group III nitride based compounds are not excluded.

The electrode to be joined to the group III nitride based compound layer, and a single-layer or multi-layer electrode to be connected with the above electrode may be formed from any conductive material. Generally, a semiconductor optical device has a pair consisting of positive and negative electrodes. One of the above electrodes may be formed from a high-reflectance metal. Iridium (Ir), platinum (Pt), rhodium (Rh), silver (Ag), aluminum(Al), palladium(Pd), an alloy including at least one thereof as a main component, or a multi-layer thereof can be suitably used as the high-reflectance metal when high-reflectance metal is directly deposited on the group III nitride based compound layer. A transparent electrodes can be used such as an oxide electrode such-as an indium tin oxide electrode or an indium titanium oxide electrode provided on the semiconductor layer. And also the high-reflectance metal may be provided on the oxide electrode. When the electrode layer is formed from a metal layer and an oxide (e.g., ITO) layer, a dielectric layer formed of any dielectric material may be provided between the oxide layer and the metal layer in order to avoid direct contact therebetween. In this case, holes are provided in the dielectric layer, and the metal layer and the oxide (e.g., ITO) layer may be electrically connected through the holes, which are filled with conductive material. The epitaxial growth wafer and the supporting substrate are preferably joined together by use of a solder. Depending on the composition of the solder, a multi-layer metal film is preferably provided, in accordance with needs, on the joint surface of the supporting substrate or the epitaxial growth wafer.

### Embodiment 1

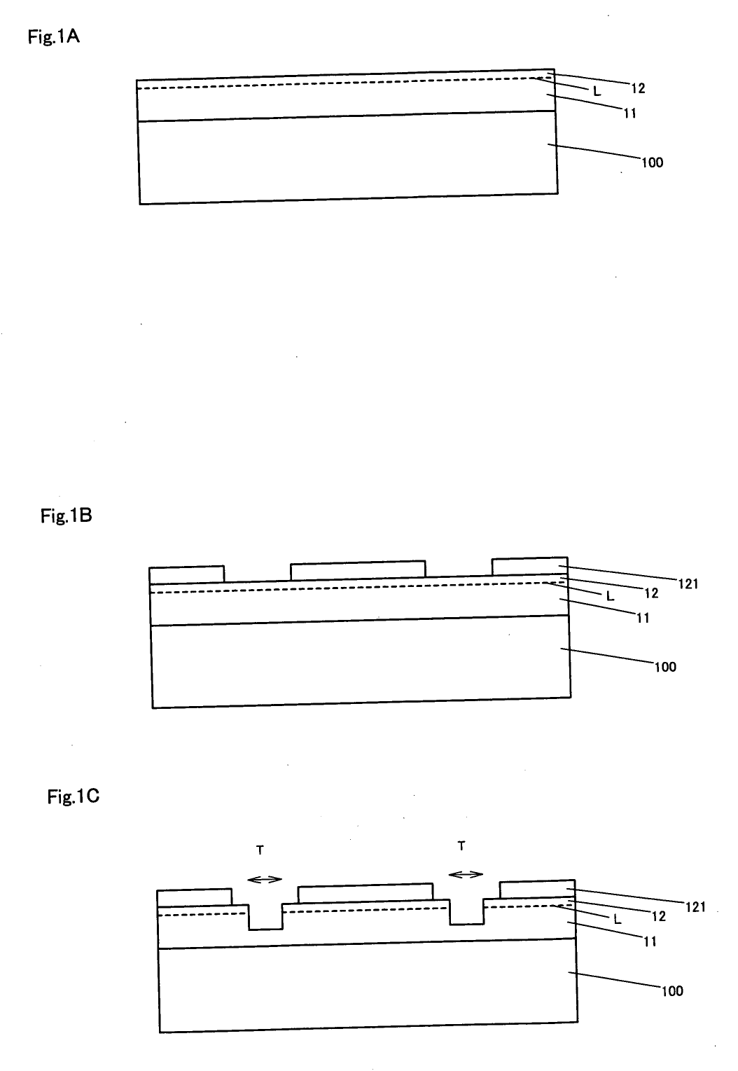

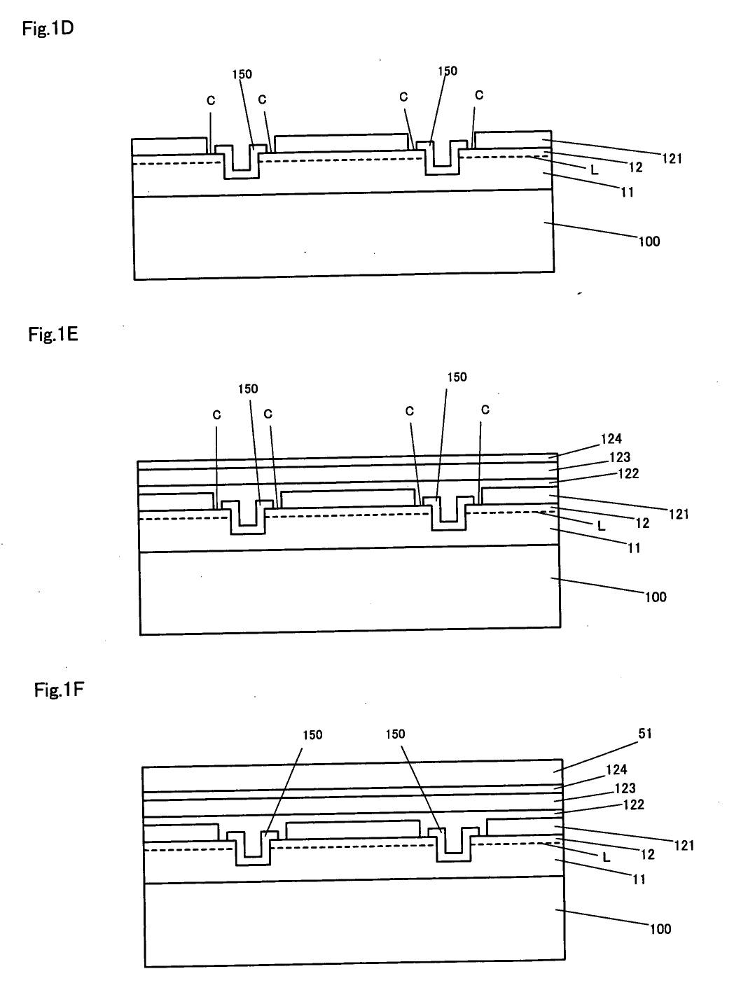

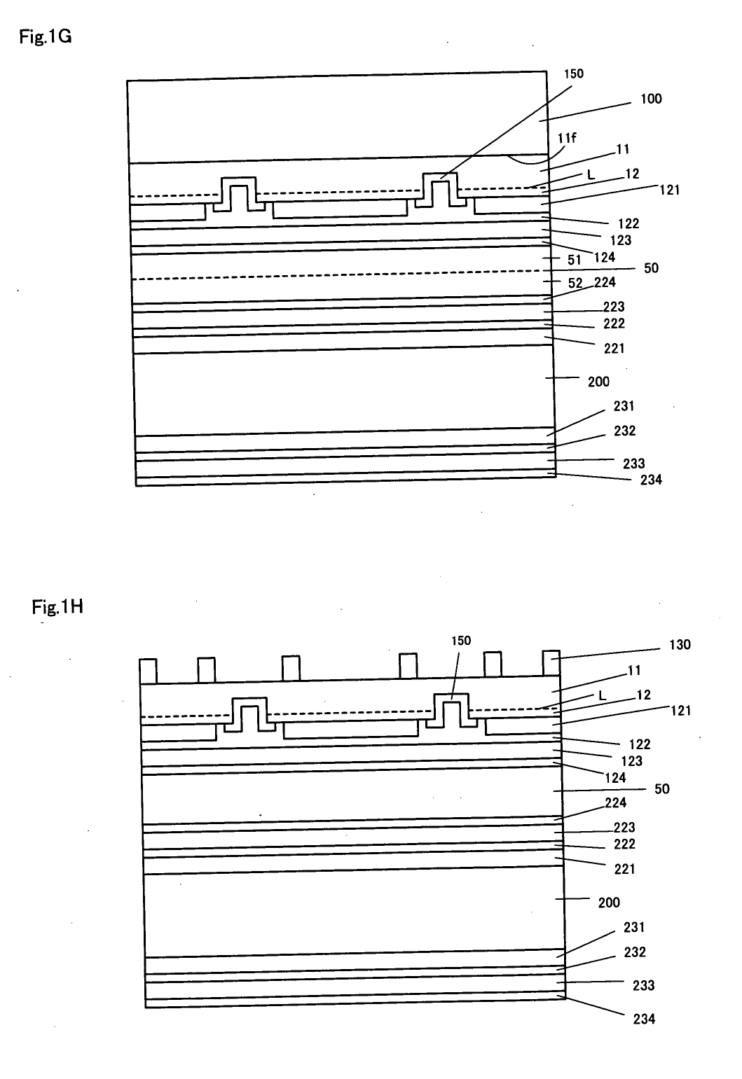

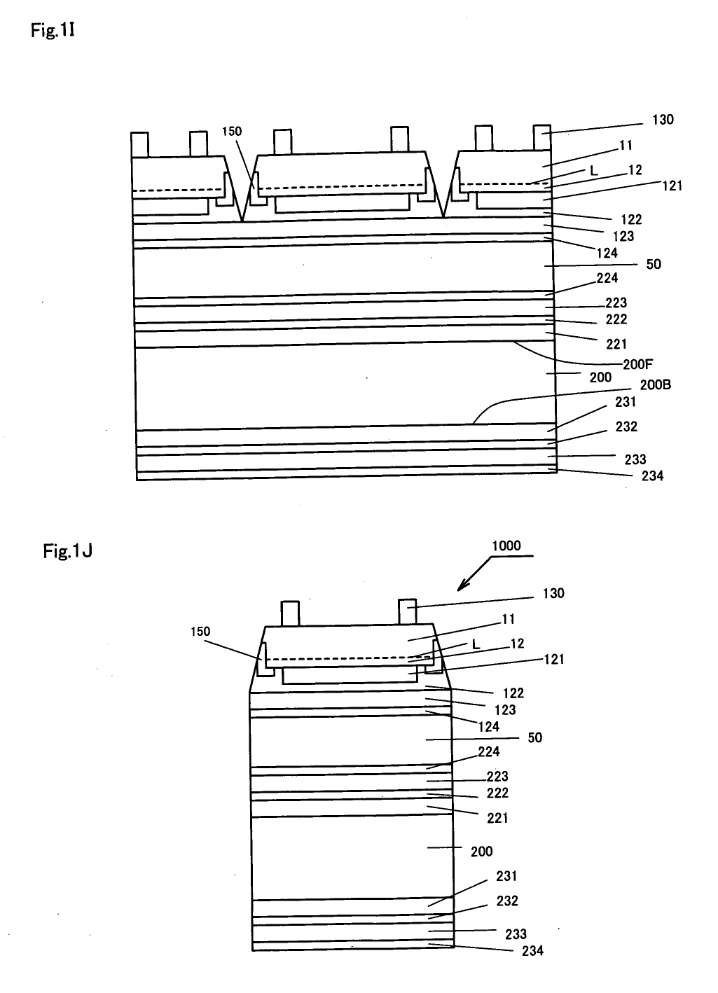

FIGS. 1A to 1J show cross-sections of a group III nitride based compound semiconductor light-emitting device 1000 in the production steps according to one embodiment of the present invention. FIG. 1J shows one chip of the group III nitride based compound semiconductor light-emitting device 1000. FIGS. 1A to 1I show cross-sections of about three chips of the device, and enlarged cross-sections of one single wafer.

Firstly, a sapphire substrate 100 is provided, and a group III nitride based compound semiconductor layer is formed on the substrate through routine epitaxial growth (FIG. 1A). FIG. 1A shows the group III nitride based compound semiconductor layer as a simplified stacked structure including an n-type layer 11 and a p-type layer 12 with a light-emitting region L. In FIGS. 1A to 1J, the n-type layer 11 and the p-type layer 12 are shown as two layers in contact with each other at the light-emitting region L represented by a broken line, and detailed stacked structures are not provided. For example, on the sapphire substrate 100, there is formed a stacked structure including a buffer layer, a silicon-doped GaN high-concentration n⁺layer, a GaN low-concentration n-type layer, and an n-AlGaN cladding layer, which are formed in this order. In this case, the stacked structure is represented by only the n-type layer 11 in FIGS. 1A to 1J. Similarly, a stacked structure including a magnesium-doped p-AlGaN cladding layer, a GaN low-concentration p-type layer, and a GaN high-concentration p⁺ layer, which are formed in this order, is represented by only the p-type layer 12 in FIGS. 1A to 1J. The light-emitting region L, which is represented by a broken line, indicates both a pn-junction face and, for example, a multiple-quantum well light-emitting layer (well layers are generally undoped) Thus, the light-emitting region L does not simply represent the interface between the n-type layer 11 and the p-type layer 12. The “plane of the light-emitting region” refers to a plane present near the light-emitting region L represented by a broken line. Before performance of “the below-mentioned heat treatment under nitrogen (N₂) atmosphere,” the p-type layer 12 is a layer containing a p-type impurity element but electric resistance thereof is not lowered. After completion of “the heat treatment under nitrogen (N₂) atmosphere,” the p-type layer 12 is a general low-resistance p-type layer.

Subsequently, a patterned resist film is formed on the p-type layer 12, and a rhodium (Rh) film (thickness: 300 nm) was vapor-deposited over the resist film. The resist film is subjected to the lift-off process, to thereby form a patterned high-reflectance electrode 121, serving as a first electrode. Specifically, the rhodium (Rh) high-reflectance electrode 121 was formed to assume a square (420 μm×420 μm) The interval between the two adjacent rhodium (Rh) high-reflectance electrodes 121 was adjusted to 80 μm. Thus, a lattice-like exposed surface of the p-type layer 12 (line width: 80 μm) was provided (FIG. 1B). Subsequently, the thus-processed stacked body was heated at 570° C. under N₂ for three minutes, to thereby lower the resistance of the p-type layer 12 and lower the contact resistance of the p-type layer 12 and the rhodium (Rh) high-reflectance electrode 121.

The center of each line portion of the lattice-like exposed p-type layer 12, serving as a chip-cutting line, was etched (width: 20 μm, depth: 3 μm) to form a lattice-form trench T (FIG. 1C). The depth of the trench T was controlled such that the bottom of the trench T was located under the light-emitting region L and sufficiently penetrated the n-type layer 11.

Subsequently, the entire surface of the wafer including the trenches T is covered with a silicon oxide (SiO₂) film. Specifically, the silicon oxide (SiO₂) film was formed so as to cover at least the side surfaces of each trench T (surfaces normal to the growth substrate) and to have a thickness of 300 nm. Subsequently, a photomask (not illustrated) was provided on an area of the silicon oxide (SiO₂) film corresponding to the bottom and side surfaces of each trench T, and the portions of the silicon oxide (SiO₂) film not covered with the photomask were removed through dry etching. After removal of the photomask, an insulating film 150 formed of silicon oxide (SiO₂) was provided on and around the trenches T. Thus, on the surface of the p-type layer 12 which is in parallel to the main surface of the substrate, lattice-form exposed surfaces C having a line width of 20 μm and separated by the trenches T were formed (FIG. 1D). On the exposed surfaces C, neither the silicon oxide (SiO₂) insulating film 150 nor the rhodium (Rh) high-reflectance electrode 121 was formed. The exposed surface C serves as a contact portion with respect to a titanium layer serving as a second electrode layer.

Next will be described formation of a multi-layer metal film through vapor deposition. Specifically, a titanium (Ti) layer 122 (thickness: 50 nm), a nickel (Ni) layer 123 (thickness: 500 nm), and a gold (Au) layer 124 (thickness: 50 nm) are sequentially formed, to thereby provide a layer structure as shown in FIG. 1E. The functions of the titanium (Ti) layer 122, nickel (Ni) layer 123, and gold (Au) layer 124 are as follows. The gold (Au) layer 124 serves as a layer for alloying with a 20%-tin gold-tin solder (Au-20Sn) 51 to be provided. The nickel (Ni) layer 123 prevents migration of tin (Sn) to the rhodium (Rh) high-reflectance electrode 121. The titanium (Ti) layer 122 enhances adhesion with respect to the nickel (Ni) layer 123 and the exposed surfaces C of the p-type layer 12.

On the gold (Au) layer 124, a 20%-tin gold-tin solder (Au-20Sn) layer 51 having a thickness of 3,000 nm is provided (FIG. 1F).

Next, an n-type silicon substrate 200 serving as a supporting substrate is provided. On each surface of the substrate, a multi-layer conductive film is formed through vapor deposition or a similar process. Specifically, layers to be formed on the surface of supporting substrate which is joined to the gold-tin solder (Au-20Sn) 51 (hereinafter referred to as a front surface) are denoted by reference numerals 221 to 224, and layers to be formed on the back surface of the substrate are denoted by reference numerals 231 to 244. On each surface of the silicon substrate 200, a titanium nitride (TiN) layer (thickness: 30 nm) 221 or 231, a titanium (Ti) layer (thickness: 50 nm) 222 or 232, a nickel (Ni) layer (thickness 500 nm) 223 or 233, and a gold (Au) layer (thickness: 50 nm) 224 or 234 were formed. The titanium nitride (TiN) layers 221 and 231 are employed by virtue of low contact resistance with respect to the n-type silicon substrate 200. The functions of the titanium (Ti) layers 222 and 232, those of the nickel (Ni) layers 223 and 233, and those of the gold (Au) layers 224 and 234 are completely the same as those of the aforementioned titanium (Ti) layer 122, nickel (Ni) layer 123, and gold (Au) layer 124, respectively. On the gold (Au) layer 224, serving as the uppermost layer of the multi-layer conductive film provided on the front surface of the n-type silicon substrate 200, a 20%-tin gold-tin solder (Au-20Sn) layer 52 having a thickness of 3,000 nm was formed. The tin 20% gold-tin solder (Au-20Sn) 51 shown in FIG. 1F is joined to the gold-tin solder (Au-20Sn) 52, whereby the wafer of the group III nitride based compound semiconductor light-emitting device is joined to the n-type silicon substrate 200. Through hot-pressing at 300° C. and 30 kgf/cm² (2.94 MPa), the two wafers are combined. Hereinafter, the gold-tin solder (Au-20Sn) will be denoted by reference numeral 50 as a unified layer (FIG. 1G).

The sapphire substrate 100 of the thus-combined wafer is irradiated with a KrF high-power pulse laser beam (248 nm). The employed irradiation conditions were an energy density of 0.7 J/cm² or higher, a pulse width of 25 ns, a unit radiation area of 2 mm×2 mm or 3 mm×3 mm, and a scanning period in the transverse direction of 10 Hz. In order to prevent overlapping of unit radiation areas, the laser beam was continuously scanned over the sapphire substrate 100. Timing of each radiation operation is determined such that contours of the unit radiation area do not exist in a single device chip. In other words, a contour of the unit radiation area is preferably present in a trench T, which is a chip separation region. Through the laser radiation, the interface 11f between the n-type layer 11 (GaN layer) and the sapphire substrate 100 is melted in the form of thin film, to thereby decompose to form gallium (Ga) droplets and nitrogen (N₂). Thereafter, the sapphire substrate 100 is removed through the lift-off process from the combined wafer. The thus-exposed surface of the n-type layer 11 is washed with dilute hydrochloric acid, to thereby remove gallium (Ga) droplets deposited on the surface.

In the subsequent step, a resist film (not illustrated) is formed over the exposed surface of the n-type layer 11. Through photolithography, the resist film is patterned to form the window portion of each device chip surrounded by a groove of a window frame shape, i.e., a hall of the resist film. On the window frame groove of the resist film, a multi-layer metal film serving as an n-type electrode 130 is formed through vapor deposition. Specifically, on the n-type layer 11, a vanadium (V) layer (thickness: 15 nm), an aluminum (Al) layer (thickness: 150 nm), a titanium (Ti) layer (thickness: 30 nm), a nickel (Ni) layer (thickness: 500 nm), and a gold (Au) layer (thickness: 500 nm) were sequentially formed. Thereafter, the resist was removed through the lift-off process, to thereby leave an n-type electrode 130 formed of a multi-layer metal film in the window frame of the resist film. In this process, the remaining metal film is removed with the resist. On each surface of the n-type silicon substrate 200, a conductive multi-layer film is formed. Thus, the produced light-emitting device has the n-type silicon substrate 200 serving as a supporting substrate; a high-reflectance metal (rhodium (Rh)) layer 121 serving as a first electrode layer on the p-type layer 12; a titanium layer 122 which is formed on the layer 121 and which is partially joined to the p-type layer 12; and a multi-layer metal film formed on the electrode layer 122. The p-type layer 12 is electrically connected, via the multi-layer metal film by the mediation of the gold-tin solder (Au-20Sn) 50, to the n-type silicon substrate 200 (FIG. 1H).

Subsequently, the n-type layer 11 is half-cut, by means of a dicing blade, at least to the depth so as to cut the silicon oxide (SiO₂) insulating film 150 formed at the bottom of the trench T. The half-cutting is not necessarily performed on the front surface 200F of the silicon substrate 200 (FIG. 1I). Subsequently, the silicon substrate 200 is also half-cut, by means of a dicing blade, on the back surface 200B where no group III nitride based compound semiconductor light-emitting layer is provided. Through breaking, respective group III nitride based compound semiconductor light-emitting devices 1000 are produced (FIG. 1J). Each group III nitride based compound semiconductor light-emitting device 1000 has a frame-form n-type electrode 130 at the periphery of the n-type layer 11, and the center area of the layer has a light-extraction area on the n-type side. The p-type electrode is electrically connected to the back surface 200 B of the silicon substrate 200 through the silicon substrate 200.

In Embodiment 1, instead of the Rh electrode 121, the first electrode layer may be formed from, for example, a reflective electrode having a three-layer structure including an indium tin oxide (ITO) transparent electrode formed on the p-type layer 12; a dielectric layer formed on the electrode, the layer having holes filled with a conductive material such as nickel; and a high-reflectance metal (e.g., aluminum or silver) layer formed on the dielectric layer. Alternatively the first electrode layer may be formed from a two-layer structure including an indium tin oxide (ITO) transparent electrode formed on the p-layer 12 and a high-reflection metal (e.g., aluminum or silver)

In Embodiment 1, the n-type electrode 130 is directly formed on the n-type layer 11. However, a window-frame-form n-type electrode may be formed after formation of, for example, a transparent electrode.

In Embodiment 1, the first electrode layer 121 may be formed from iridium (Ir), platinum (Pt), silver (Ag), aluminum(Al), palladium(Pd), an alloy including at least one thereof as a main component, or a multi-layer thereof other than rhodium (Rh).

In Embodiment 1, the electrode layer 122 is formed from chromium (Cr), molybdenum (Mo), tantalum (Ta), vanadium (V), tungsten (W), an alloy including at least one thereof as a main component, or a multi-layer thereof other than titanium (Ti).

What is claimed is:

1. A method for producing a group III nitride based compound semiconductor device, including separating the device into individual chips by means of a dicing blade, the method comprising:
a portion of an epitaxial layer where a dicing blade is to be positioned is partially or totally removed through etching, to thereby form a trench;
forming insulating film on the bottom and on the side surfaces of the trench; and
performing dicing in such a manner that the bottom of the trench is removed by means of the dicing blade without completely removing the side surfaces of the insulating film,
wherein the insulting film is formed on the side surfaces of the trench such that the film covers a p-type layer to an n-type layer included in group III nitride based compound semiconductor layers so as to prevent short circuit between the p-type layer and the n-type layer.

2. A method for producing a group III nitride based compound semiconductor device as described in claim 1, wherein the etching and formation of the insulating film is carried out from one conduction-type layer of the group III nitride based compound semiconductor device, and the dicing by means of the dicing blade is carried out from the other conduction-type layer of the same device.

3. A method for producing a group III nitride based compound semiconductor device as described in claim 2, wherein, before dicing through operation of the dicing blade, the method further comprises:
forming, on the first substrate, a group III nitride based compound semiconductor device;
forming an electrode on the uppermost layer of the device;
forming the trench;
forming the insulating film;
bonding a conductive second substrate, directly or by the mediation of a conductive film or a conductive multi-layer film, to the electrode-formed surface of the group III nitride based compound semiconductor device formed on the first substrate;
removing the first substrate from the bonded structure; and
forming an electrode on a newly exposed layer of the group III nitride based compound semiconductor device.

4. A group III nitride based compound semiconductor device, which comprises:
a conductive substrate,
a first electrode joined to the conductive substrate directly or by the mediation of a conductive film or a conductive multi-layer film,
a group III nitride based compound semiconductor device layer in which at least a first conduction-type layer joined to the first electrode and a second conduction-type layer having a conduction type differing that of the first-conduction type layer are stacked,
a second electrode formed on the surface of the group III nitride based compound semiconductor device layer opposite the surface on which the first electrode has been formed, and
an insulating film extending along and proximal to the outer periphery of the device and formed so as to cover the side surfaces of the layers having an opposite conduction type and being included in the group III nitride compound semiconductor device layer.
